(19) United States
(12) Patent Application Publication
(10) Pub. No.: US 2025/0053153 A1
(43) Pub. Date: Feb. 13, 2025

(54) POWDER DEGRADATIONS

(71) Applicant: Hewlett-Packard Development Company, L.P., Spring, TX (US)

(72) Inventors: Jacob Tyler WRIGHT, San Diego, CA (US); Sunil KOTHARI, Palo Alto, CA (US); Maria Fabiola LEYVA MENDIVIL, Guadalajara (MX); Jun ZENG, Palo Alto, CA (US)

(73) Assignee: Hewlett-Packard Development Company, L.P., Spring, TX (US)

(21) Appl. No.: 18/720,529

(22) PCT Filed: Dec. 17, 2021
(86) PCT No.: PCT/US2021/064154

§ 371 Date: Jun. 14, 2024

(51) Int. Cl. G05B 19/4099; G06F 30/17

(52) U.S. Cl. CPC G05B 19/4099; G06F 30/17; G05B 2219/49023

(57) ABSTRACT

Examples of methods are described. In some examples, a method includes determining objects corresponding to a manufacturing period of three dimensional (3D) printing. In some examples, the method includes packing build volumes based on the objects. In some examples, the method includes simulating manufacturing powder degradation based on the build volumes. In some examples, the method includes determining a quantity of manufacturing powder consumption based on the manufacturing powder degradation. In some examples, the method includes adjusting a manufacturing parameter based on the quantity of manufacturing powder consumption.

### BACKGROUND

Additive manufacturing is a technique to form three-dimensional (3D) objects by adding material until the object is formed. The material may be added by forming several layers of material with each layer stacked on top of the previous layer. Examples of additive manufacturing include melting a filament to form each layer of the 3D object (e.g., fused filament fabrication), curing a resin to form each layer of the 3D object (e.g., stereolithography), sintering, melting, or binding powder to form each layer of the 3D object (e.g., selective laser sintering or melting, multi jet fusion, metal jet fusion, etc.), and binding sheets of material to form the 3D object (e.g., laminated object manufacturing, etc.).

### BRIEF DESCRIPTION OF THE DRAWINGS

FIG. 1 is a flow diagram illustrating an example of a method for manufacturing control based on powder degradation;

FIG. 2 is a flow diagram illustrating an example of a method for manufacturing control based on powder degradation;

FIG. 3 is a block diagram of an example of an apparatus that may be used in controlling manufacturing based on powder degradation;

FIG. 4 is a block diagram illustrating an example of a computer-readable medium for controlling manufacturing based on powder degradation;

FIG. 5 is a diagram illustrating examples of box and whisker charts in accordance with some examples of the techniques described herein; and

FIG. 6 is a block diagram illustrating an example of engines to simulate how much powder degradation will occur for a build volume.

### DETAILED DESCRIPTION

Additive manufacturing may be used to manufacture three-dimensional (3D) objects. 3D printing is an example of additive manufacturing. Manufacturing powder (and/or “powder” herein) is particles of material for manufacturing an object or objects. For instance, polymer particles are an example of manufacturing powder. In some examples, an object may indicate or correspond to a region (e.g., area, volume, etc.) where particles are to be sintered, melted, or solidified. For example, an object may be formed from sintered or melted powder. In many types of 3D printing, layers of manufacturing powder are delivered to a build volume. After each layer is delivered, heat is applied to portions of the layer to cause the powder to coalesce (e.g., sinter) in those portions and/or to remove solvents from a fusing agent or binding agent. For example, a fusing agent or a binding agent may be applied to some portions for coalescence or binding, and/or a detailing agent may be applied to some portions to avoid coalescence. An energy source may deliver energy that is absorbed by the fusing agent or binding agent to cause the powder to coalesce. Additional layers are delivered and selectively heated to build up a 3D object from the coalesced powder. After the layers have been delivered and heated, the build volume may be allowed to cool for a period of time. The 3D objects are then removed from the powder bed. The remaining powder can be recycled or discarded. Recycling the powder reduces waste and reduces the cost of printing each object.

Manufacturing powder may degrade and oxidize when exposed to elevated temperatures and oxygen. For example, polymer powders, such as polyamide 12 (PA 12), may degrade during 3D printing due to the exposure to air, humidity, and/or elevated temperatures. For instance, oxidation may occur due to environmental exposure (e.g., contact with air and/or humidity). In some examples, the powder may spend 30 to 40 hours above 160° C. during the printing and cooling process, which may cause powder degradation. Repeated printing may cause the powder to become degraded enough to affect the 3D printing process. For example, degraded powder may cause surface distortions, such as an orange peel effect, poor mechanical properties, off-gassing that creates porosity in the object, and the like. In some examples of manufacturing powder (e.g., PA 12), degradation may become evident with yellowing of the manufacturing powder. In some examples of manufacturing powder (e.g., PA 11, metals, etc.), degradation may occur while being less visibly evident or without being visibly evident.

Various remediation techniques may be used to limit the degradation. For example, antioxidant packages may be included inside the powder, but the degradation may still occur. For instance, anti-oxidation additives and flowability additives may break down at high temperatures, which may contribute to powder yellowing. Some agents may worsen powder yellowing, which may imply that degradation is affected by a combination of gases in the powder. Using a nitrogen environment during 3D printing can reduce oxidation. However, gases (e.g., oxygen) can be dissolved in the powder or can enter the powder. Accordingly, the remediation techniques may have limited effectiveness. Moreover, the remediation techniques may increase the printing cost.

In some examples, polymers may degrade due to temperature and oxygen reactions. Temperature increases molecular mobility, allowing polymer chains to increase in length (post-condensation), cross-link with other chains and, with further degradation, strip or even split the chain (e.g., chain stripping, chain scission, respectively). Gases (e.g., oxygen) may react with the polymer molecules causing post-condensation at early stages of degradation, branching of the polymer chains, and, as the reaction continues, scission of the polymer chains. Together with other additives in the powder, the degradation may change the molecular weight of powder particles. Molecular weight distribution may be a significant factor in determining the mechanical properties of the powder and/or objects manufactured from the powder.

In some examples, the degradation may be remediated by mixing fresh powder with recycled powder. As used herein, the term “fresh powder” refers to powder that has not been used for 3D printing, and the term “recycled powder” refers to powder that has been through the 3D printing process. In some examples, using fresh powder for each printing of a new build volume may be non-optimal in terms of powder consumption and may affect material properties of the powder. In some examples, PA 12 powder quality may increase for a few cycles before the material properties start deteriorating. In some cases, using too much recycled powder may tend to significantly increase powder stress. In some examples, powder may experience a journey from zero thermal stress to repeated stress until the powder degradation reaches a plateau, after which more cycles may seriously affect manufactured object properties.

Some approaches to reducing powder consumption may recommend a refresh ratio (e.g., ratio of fresh powder to recycled powder) based on packing density and build height. With a minimum object spacing (e.g., 3 millimeters (mm)), a relationship between a mass of fresh powder consumed versus build height may be observed for different packing densities to maintain a target quality metric (e.g., b* of 4 as described below). In some examples, taller build heights may generally consume more fresh powder. However, the observed relationship is non-linear with roughly half volume builds consuming a similar amount of fresh powder despite differences in build height and packing density. Accordingly, other factors besides packing density alone may affect the refresh ratio. Some examples of the techniques described herein may reduce powder consumption and/or manufacturing time while increasing yield and/or packing density.

A quality metric may be used to determine the amount of degradation of the powder. For example, the quality metric may be the relative solution viscosity, the molecular weight, or the like, which may correlate with the amount of degradation. In some examples, the quality metric may be a measurement of color. For instance, the amount of degradation of PA 12 is highly correlated with the color of the powder. For example, the amount of degradation may be highly correlated with the b* component of the Commission on Illumination L*a*b* (CIELAB) color space. In some examples, degradation and/or powder quality may be measured and/or represented with b*. For instance, the quality metric may be associated with powder color (e.g., yellowness index (YI), American Society for Testing and Materials (ASTM) E313). In some examples, fresh powder may be added to recycled powder to keep a quality metric above a threshold. For example, a user may target to use powder with a b* of less than 4.

It can be difficult to discern a degree to which powder will degrade during a particular print. The degradation is affected by the ability of gases to diffuse into the surrounding environment, which in turn depends on the arrangement of parts, and by the amount of agent (e.g., a detailing agent, a color agent, or the like) delivered to the powder. Some examples of the techniques described herein may quantify the effect of gas (e.g., oxygen) diffusion through powder and/or around an object. For example, some approaches may extract geometric attributes at a voxel level. The extracted geometric representations may be utilized to produce a voxel level powder degradation prediction with increased accuracy. For instance, some examples of the techniques described herein may enhance the accuracy of powder degradation prediction at individual voxel locations and/or overall (e.g., for an entire build). Enhanced powder degradation prediction may enable reducing fresh powder consumption in some examples.

A voxel is a representation of a location in a 3D space. For example, a voxel may represent a volume or component of a 3D space. For instance, a voxel may represent a volume that is a subset of the 3D space. In some examples, voxels may be arranged on a 3D grid. For instance, a voxel may be rectangular or cubic in shape. Examples of a voxel size dimension may include 25.4 mm/150≈170 microns for 150 dots per inch (dpi), 490 microns for 50 dpi, 0.5 mm, 1 mm, 2 mm, 4 mm, 5 mm, etc. A set of voxels may be utilized to represent a build volume. The term “voxel level” and variations thereof may refer to a resolution, scale, and/or density corresponding to voxel size.

A build volume is a volume in which an object or objects may be manufactured. For instance, a build volume may be a representation of a physical volume and/or may be an actual physical volume (e.g., a print chamber or build chamber) in which an object or objects may be manufactured. A “build” may refer to an instance of 3D manufacturing. For example, a build may geometrically represent an object region(s) and/or a non-object region(s) (e.g., unfused powder region(s)). A build may be included in and/or occupy a build volume for manufacturing. A layer is a portion of a build volume. For example, a layer may be a cross section (e.g., two-dimensional (2D) cross section or a 3D portion) of a build volume. In some examples, a layer may be a slice with a thickness (e.g., 80 micron thickness or another thickness) of a build volume. In some examples, a layer may refer to a horizontal portion (e.g., plane) of a build volume. In some examples, an “object” may refer to an area and/or volume in a layer and/or build volume indicated for forming an object.

Some examples of the techniques described herein may quantify the effect of voxel exposure to oxygen and/or other gases in relation to voxel location and neighborhood. Object voxels may affect the diffusion of gases. Voxels farther away from the object(s) may be able to more readily diffuse gases with other voxels. Powder voxel location may also affect the diffusion of gases since voxels closer to the sides and further down in a build chamber may be less open to diffusion than voxels at the center and near the top of the build chamber. In some examples, a powder voxel may be a voxel that includes powder (e.g., a non-object voxel). In some examples, powder voxel location may be indicated with coordinates (e.g., X, Y, Z coordinates) and/or indices corresponding to the build volume.

Some examples of the techniques described herein may utilize a machine learning model or models. Machine learning is a technique where a machine learning model is trained to perform a task or tasks based on a set of examples (e.g., data). Training a machine learning model may include determining weights corresponding to structures of the machine learning model. Artificial neural networks are a kind of machine learning model that are structured with nodes, model layers, and/or connections. Deep learning is a kind of machine learning that utilizes multiple layers. A deep neural network is a neural network that utilizes deep learning.

Examples of neural networks include convolutional neural networks (CNNs) (e.g., basic CNN, deconvolutional neural network, inception module, residual neural network, etc.), recurrent neural networks (RNNs) (e.g., basic RNN, multi-layer RNN, bi-directional RNN, fused RNN, clockwork RNN, etc.), graph neural networks (GNNs), autoencoders, variational autoencoders (VAEs), etc. Different depths of a neural network or neural networks may be utilized in accordance with some examples of the techniques described herein. Some examples of the techniques described herein may utilize a machine learning model (e.g., deep learning network) to extract physical representative attributes for voxels at a given location.

While plastics (e.g., polymers) may be utilized as a way to illustrate some of the approaches described herein, some the techniques described herein may be utilized in various examples of additive manufacturing. For instance, some examples may be utilized for plastics, polymers, semi-crystalline materials, metals, etc. Some additive manufacturing techniques may be powder-based and driven by powder fusion (e.g., area-based powder bed fusion-based additive manufacturing). Some examples of the approaches described herein may be applied to additive manufacturing techniques such as stereolithography (SLA), multi jet fusion (MJF), metal jet fusion, selective laser melting (SLM), selective laser sintering (SLS), liquid resin-based printing, etc. Some examples of the approaches described herein may be applied to additive manufacturing where agents carried by droplets are utilized for voxel-level thermal modulation.

Throughout the drawings, similar reference numbers may designate similar or identical elements. When an element is referred to without a reference number, this may refer to the element generally, with and/or without limitation to any particular drawing or figure. In some examples, the drawings are not to scale and/or the size of some parts may be exaggerated to more clearly illustrate the example shown. Moreover, the drawings provide examples in accordance with the description. However, the description is not limited to the examples provided in the drawings.

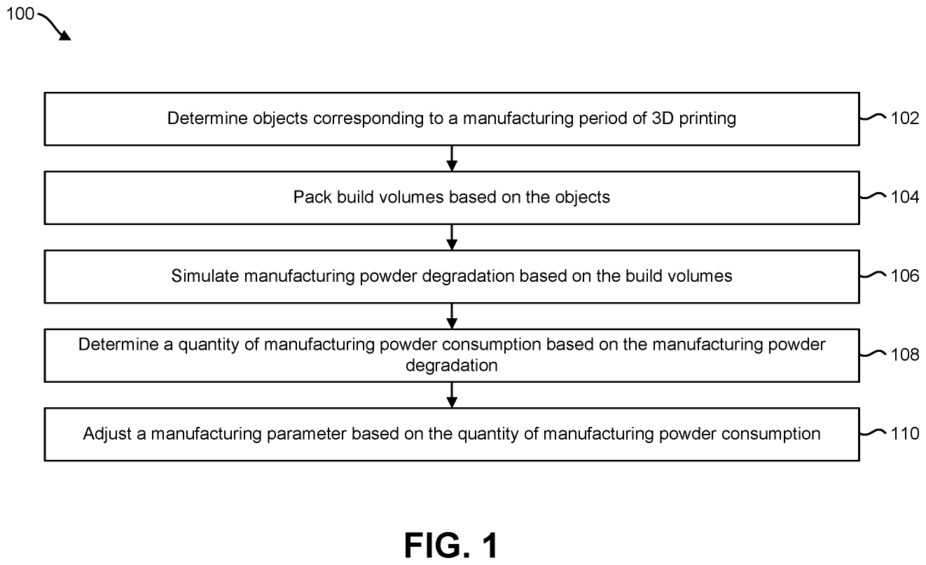

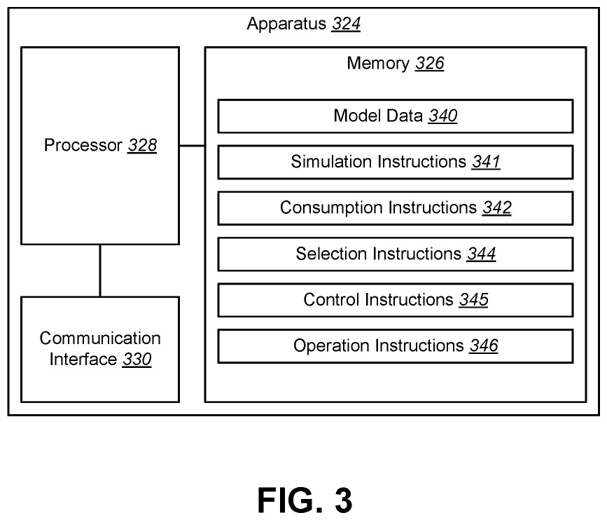

FIG. 1 is a flow diagram illustrating an example of a method 100 for manufacturing control based on powder degradation. For example, the method 100 may be performed to control an aspect or aspects of object manufacturing. The method 100 and/or an element or elements of the method 100 may be performed by an electronic device. For example, the method 100 may be performed by the apparatus 324 described in relation to FIG. 3.

The apparatus may determine 102 objects corresponding to a manufacturing period of 3D printing. A manufacturing period is a range of time in which objects have been manufactured. For instance, printing instructions may be provided to a 3D printer or 3D printers (e.g., 3D printers at a factory or manufacturing plant) to manufacture an object or objects over time. A manufacturing period may indicate a previous time range in which objects have been manufactured. For instance, a manufacturing period may be an hour, hours, a day, days, a week, weeks, a month, or months, etc.

In some examples, a manufacturing period may be indicated by a received input (from a user, for instance). For example, an input may be received from a keyboard, mouse, and/or touchscreen, etc., indicating a manufacturing period. In some examples, a default manufacturing period(s) may be utilized. For instance, a default manufacturing period may be set and/or utilized. In some examples, a manufacturing period may be from three weeks previous to a current time.

Determining 102 objects corresponding to a manufacturing period may include determining object models corresponding to manufactured objects in the manufacturing period. For instance, the apparatus may retrieve object models (e.g., from memory, from a storage device, from a remote server, etc.) corresponding to objects manufactured during the manufacturing period. For example, the apparatus may look up object models from a repository (e.g., database, files, etc.) corresponding to printing instructions executed within the manufacturing period. In some examples, multiple manufacturing periods may be utilized. For instance, the apparatus may retrieve object models corresponding to objects manufactured in multiple manufacturing periods.

In some examples, determining 102 the objects may include selecting the objects based on an object category or categories. An object category is data indicating an attribute or characteristic of an object or objects. For instance, an object category may indicate an object function or type (e.g., soles for toe arch correction, soles for heel spur cushioning, soles for plantar fasciitis treatment, ankle orthotic, etc.), an object size (e.g., shoe soles for size 10 shoes), an object color, etc. For instance, the apparatus may select objects from a distribution of objects to get a sampling of an object category or categories. In some examples, an object category or categories may be indicated by metadata associated with each object in an object model repository.

In some examples, the apparatus may pack 104 build volumes based on the objects. For instance, the apparatus may arrange and/or fit the objects (e.g., object models) into the build volumes. In some examples, the apparatus may perform a packing procedure that includes placing object models with random orientations into a build volume, detecting collisions, and/or iterating to produce a packing. The apparatus may pack 104 multiple build volumes, where different build volumes may be packed differently.

In some examples, the apparatus may determine a quantity of build volumes. For example, the apparatus may determine the quantity of build volumes to be evaluated for powder degradation and/or powder consumption, where the build volumes may be packed in accordance with a criterion or criteria (e.g., batch size(s) and/or object spacing(s), etc.). For instance, the apparatus may determine a quantity of build volumes to pack based on a factor or factors. In some examples, determining the quantity of build volumes may be based on a quantity of object packing amounts, a quantity of object spacings, and/or a quantity of replicants. In some examples, the quantity of object packing amounts, the quantity of object spacings, and/or the quantity of replicants may be received from an input device (e.g., keyboard, mouse, touchscreen, etc.). For instance, the apparatus may receive a user input(s) indicating the quantity of object packing amounts, the quantity of object spacings, and/or the quantity of replicants.

In some examples, a quantity of build volumes B may be calculated based on a quantity of object packing amounts (e.g., 30 object packing amounts that sweep from 5-35 object pairs in a build volume for orthotics), a quantity of object spacings to evaluate (e.g., 3 spacings for orthotics: 2 mm, 2.5 mm, 3 mm), and a quantity of replicants per condition (e.g., 5 for orthotics). In some examples, the apparatus may multiply the quantity of object packing amounts, the quantity of object spacings, and the quantity of replicants to produce the quantity of build volumes B. For instance, 30 object packing amounts*3 object spacings*5 replicants=450 build volumes. In some examples, factors may vary between different objects and/or factories. For instance, the quantity of object packing amounts, quantity of object spacings, and/or the quantity of replicants may be chosen based on the geometries being printed.

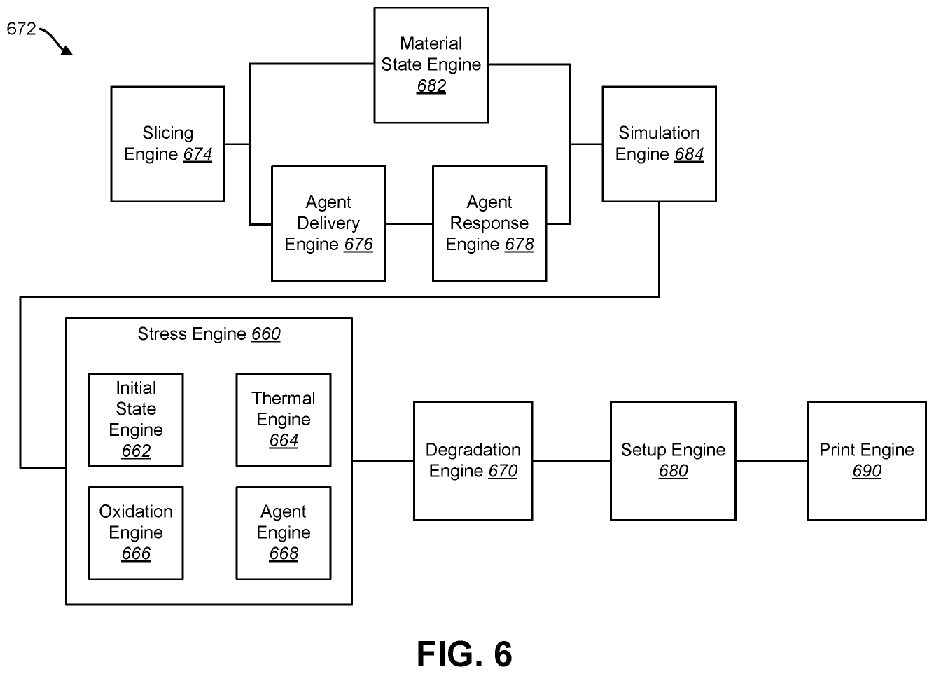

The apparatus may simulate 106 manufacturing powder degradation based on the build volumes. For instance, the apparatus may simulate manufacturing powder degradation for the powder in each of the build volumes. In some examples, the simulation may include a first principles (e.g., finite element analysis (FEA)) approach, a machine learning approach, or a combination thereof. For instance, a simulation may determine an amount of stress and/or degradation experienced by each voxel of the build volume that would occur during manufacturing. An example of an approach to simulate 106 manufacturing powder degradation is given in relation to FIG. 6. In some examples, build heights and/or packing densities may be outputs of a packing simulation and may be tracked. In some examples, build height and/or packing density may not be an input(s) to the packing simulation. In some examples, simulation 106 may be performed over a period (e.g., seconds, minutes, hours, days, etc.).

The apparatus may determine 108 a quantity of manufacturing powder consumption based on the manufacturing powder degradation. For instance, the manufacturing powder degradation may indicate the degradation of a voxel or voxels of a build volume (e.g., each build volume simulated). The manufacturing powder degradation may be utilized to determine 108 the quantity of manufacturing powder consumption. A quantity of manufacturing powder consumption is an amount of manufacturing powder consumed to manufacture an object or objects. For instance, the quantity of manufacturing powder consumption may be an amount of fresh powder to mix with recycled powder (to maintain a target quality metric, for example).

In some examples, the apparatus may determine 108 the quantity of manufacturing powder consumption in accordance with one, some, or all of the following Equations. Equation (1) expresses an approach for determining an aggregate quality level (in terms of b*) of voxels of equal mass.

$${Q}_{level} = \sqrt{\frac{1}{n} {\sum }_{i = 1}^{n} {b}_{1}^{2}} \qquad ( 1 )$$

In Equation (1), Qₗₑᵥₑₗ is the aggregate quality level, b is a quality metric (e.g., b*) for a voxel i, n is a quantity of voxels of equal mass (e.g., voxels of recyclable powder), and i is an index of the voxels.

Equation (2) expresses an approach for determining an aggregate quality level (in terms of b*) of voxels of mass m.

$${Q}_{level} = \sqrt{\frac{{\sum }_{i = 1}^{N} {m}_{i} {b}_{i}^{2}}{{\sum }_{i = 1}^{N} {m}_{i}}} \qquad ( 2 )$$

In Equation (2), Qₗₑᵥₑₗ is the aggregate quality level, b is a quality metric (e.g., b*) for a voxel i, N is a quantity of voxels (e.g., voxels of recyclable powder), m is a mass of voxel i, and i is an index of the voxels. In some examples, the apparatus may determine the aggregate quality level of voxels based on the estimated powder degradation (e.g., quality metrics of the voxels). For instance, the aggregate quality level may be determined in accordance with Equation (1) and/or Equation (2).

Equation (3) expresses an approach for determining a refresh ratio to produce a powder blend with a target quality level.

$$R = \frac{{b}_{t}^{2} - {b}_{r}^{2}}{{b}_{f}^{2} - {b}_{r}^{2}} \qquad ( 3 )$$

In Equation (3), R is the refresh ratio, bₜ is the target quality level, bᵣ is the quality level of the voxels of recyclable powder, and b_{f} is the quality level of fresh powder.

Equation (4) expresses an approach for determining a mass of fresh powder to produce a powder blend with a target quality level.

$${m}_{f} = \frac{{m}_{r} ⋆ R}{1 - R} \qquad ( 4 )$$

In Equation (4), m_{f} is the mass of fresh powder and mᵣ is a mass of voxels of recyclable powder. In some examples, the apparatus may determine a mass of fresh powder (e.g., m_{f}) to produce a powder blend with a target quality level. For instance, the apparatus may determine the mass of fresh powder in accordance with Equation (4). In some examples, the mass of fresh powder may be an example of the quantity of manufacturing powder consumption.

In some examples, determining a quantity of recyclable powder may include determining a mass of the recyclable powder (e.g., mᵣ) corresponding to recyclable voxels. For instance, the apparatus may determine the mass of recyclable powder by adding the voxel masses of the recyclable voxels and/or for equal voxel mass, multiplying a voxel mass by a quantity of recyclable voxels. The mass of the recyclable powder (e.g., mᵣ) may be utilized to determine the mass of fresh powder (e.g., m_{f}) to produce a powder blend with a target quality level.

In some examples, the apparatus may determine recyclable voxels from reclaimable voxels. Reclaimable powder is powder that is accessible (e.g., powder that is not stuck to the surface of an object, powder that is outside of the object or objects, etc.). Reclaimable voxels are voxels corresponding to reclaimable powder. Recyclable powder is powder that is determined for recycling. For example, recyclable powder may be the reclaimable powder or a subset of the reclaimable powder. Recyclable voxels are voxels corresponding to recyclable powder. In some examples, recyclable powder may correspond to recyclable voxels determined (e.g., selected) from reclaimable voxels.

In some examples, the apparatus may utilize a binary search approach to iteratively remove a portion of the reclaimable voxels such that the remaining recyclable voxels mixed with fresh powder may maintain a target quality level. In some examples, a binary search approach may be utilized to achieve a powder-neutral build. A powder-neutral build is a build where the total mass of powder and (e.g., plus) objects in the build volume before recyclable and/or recycling is approximately equal to the total mass of recyclable powder and (e.g., plus) fresh powder. The total mass of the objects and powder for a build may be established factors. The mass and quality level (e.g., b*) of the recyclable powder may depend on a fraction of the reclaimable powder that is excluded. The mass of fresh powder to produce blended powder at a target quality level (e.g., target b*) may be determined in accordance with Equation (4) above (and may be deterministic based on the recyclable powder level). The binary search approach may be iteratively calculated. In some examples, a closed form approach may be utilized.

The binary search approach may utilize a percentile estimate. The percentile estimate may represent a proportion (e.g., mass fraction) of reclaimable powder to be reclaimed (e.g., non-excluded powder). For instance, the percentile estimate may be a ratio of a mass of recyclable powder and a mass of reclaimable powder. For instance, a percentile estimate of 0.9 may mean that 0.9 or 90% of reclaimable powder (e.g., powder to be reclaimed) and/or that 0.1 or 10% of reclaimable powder (e.g., the worst 10%) is to be excluded. The percentile estimate may be initialized to a value (e.g., 0.5).

The binary search approach may include a quantity of iterations (e.g., K). For instance, a loop operation or operations may iterate for a variable k in a range (e.g., k=1, 2, . . . , K, where K=11 or another number). Equation (5) illustrates an example of a loop operation in a binary search approach.

$$( {b}_{r} , {m}_{r} ) = calc\_remix ( vbuild , {fraction}_{r} = percentile ) \qquad ( 5 )$$

In Equation (5), bᵣ is the quality level of the recyclable powder, mᵣ is a mass of recyclable powder, calc_remix is a remix calculation function, build is a build being evaluated, fractionᵣ is a fraction of reclaimable powder to be reclaimed, and percentile is the percentile estimate. For instance, the calc_remix function may be utilized to determine the mass and b* value of a blend including all reclaimable powder below a b* percentile (e.g., percentile 0.9 may mean that the worst 10% of reclaimable powder is excluded from the recyclable powder). In some examples, the calc_remix function may take the build voxels (“vbuild”), each having a mass and b* value, and fractionᵣ. The calc_remix function may filter the build voxels to the least degraded powder voxels. For instance, if fractionᵣ=0.9, the worst 10% of voxels are removed from consideration. The calc_remix function may compute the mass mᵣ (e.g., a summation of powder mass for each voxel under consideration) and the b* of the aggregate blend in accordance with the equation:

$${b}_{r} = \sqrt{\frac{\sum {{m}_{i} ( {b}_{i} )}^{2}}{\sum {m}_{i}}} ,$$

where mᵢ is the mass of voxel i (of the filtered voxels) and bᵢ is the b* value of voxel i.

Equation E (6) illustrates an example of an operation to calculate a mass of fresh powder based on mass of quality level of recyclable powder and mass of recyclable powder. The operation may be a loop operation in a binary search approach.

$${m}_{f} = calc\_fresh ( {b}_{t} , {b}_{r} , {m}_{r} ) \qquad ( 6 )$$

In Equation (6), bₜ is a target quality level, bᵣ is the quality level of the recyclable voxels and/or powder, mᵣ is a mass of recyclable voxels and/or powder, m_{f} is the mass of fresh powder, and calc_fresh is a fresh powder mass calculation function. In some examples, the calc_fresh function may be a combination of Equations and (3) (4),

$$( e . g . , R = \frac{{b}_{t}^{2} - {b}_{r}^{2}}{{b}_{f}^{2} - {b}_{r}^{2}} and {m}_{f} = {m}_{r} ⋆ \frac{R}{1 - R} ) .$$

For instance, the refresh ratio (e.g., R) to achieve the target b* level may be determined first. Then, the mass of fresh powder (e.g., m_{f}) may be determined based on R and mᵣ.

Equation (7) illustrates an example of an operation to calculate a mass difference. The operation may be a loop operation in a binary search approach.

$${m}_{Δ} = {m}_{b} - ( {m}_{r} + {m}_{f} ) \qquad ( 7 )$$

In Equation (7), m_{Δ} is the mass difference, m_{b} is a build mass (e.g., total mass of powder mass+object(s) mass in a build), mᵣ is a mass of recyclable voxels and/or powder, and m_{f} is the mass of fresh powder.

In an example of the binary search approach, the percentile estimate may be updated based on a comparison of a net mass (e.g., m_{Δ}) and a threshold. For example, if net mass is less than 0, then the percentile estimate may be updated in accordance with Equation (8).

$$percentile = percentile + {( \frac{1}{2} )}^{( k + 1 )} \qquad ( 8 )$$

Otherwise, the percentile mass may be updated in accordance with Equation (9).

$$percentile = percentile - {( \frac{1}{2} )}^{( k + 1 )} \qquad ( 9 )$$

At the end of the loop (e.g., iterating 10 times, from k=1 to k=10), the apparatus may have calculated a percentile threshold for excluded powder to remain powder neutral (e.g., the percentile threshold may be calculated to within 0.00097 in a 0-1 range). For example, the percentile estimate may be a value such as 0.85, meaning that the worst 15% of the reclaimable powder is excluded from the recyclable powder. In some examples, excluding the calculated amount for a full build may reduce the amount of fresh powder used to achieve the target quality level (e.g., b* level) by several kilograms.

The apparatus may adjust 110 a manufacturing parameter based on the quantity of manufacturing powder consumption. A manufacturing parameter is a setting, rule, or criterion to control a manufacturing procedure. For instance, the apparatus may control a manufacturing procedure by adjusting a manufacturing parameter. Examples of manufacturing parameters may include a batching rule, a build height rule, a spacing rule, etc. A batching rule is a rule that indicates a target or threshold quantity of objects to be packed in a build volume. A build height rule is a target or threshold height of a packing of objects in a build volume. A spacing rule is a quantity indicating a target or threshold amount of spacing between objects to be packed in a build volume. In some examples, adjusting 110 the manufacturing parameter based on the quantity of manufacturing powder consumption may include setting the manufacturing parameter(s) to reduce manufacturing powder consumption for subsequent manufacturing.

In some examples, the method 100 may include determining 108 the quantity of manufacturing powder consumption per object for each of the build volumes. For instance, the apparatus may determine a quantity of manufacturing powder consumption per object for each of the build volumes. The apparatus may select a build volume with a smallest quantity of manufacturing powder consumption per object. Adjusting 110 the manufacturing parameter may include changing a manufacturing parameter (e.g., batching rule, build height rule, spacing rule, etc.) based on the selected build volume. For instance, the apparatus may change the batching rule to have a target amount of objects in the build volume for manufacturing. The apparatus may utilize the adjusted manufacturing parameter to pack objects in subsequent manufacturing. For instance, if the selected build volume (with the smallest quantity of manufacturing powder consumption per object, for example) has 28 objects packed, the apparatus may set the batching rule to pack 28 objects in each build volume.

In some examples, adjusting 110 the manufacturing parameter may include changing a build height rule. For instance, if the selected build volume (with the smallest quantity of manufacturing powder consumption per object, for example) has a build height of 110 mm, the apparatus may set the build height rule to utilize packings under 110 mm (or within a range of 110 mm, for instance) in each build volume.

In some examples, based on simulating each build volume, the apparatus may utilize the simulation results to determine a manufacturing powder consumption per object. For instance, the manufacturing powder consumption may be calculated from the simulation results (e.g., manufacturing powder degradation), which may indicate an amount of powder to recycle from the build to refill the powder supply and a percentage of fresh powder to counteract the manufacturing powder degradation that occurred from manufacturing. MJF printing often leaves a surplus of used powder. The powder consumption of a build may be calculated by dividing the number of objects manufactured by the mass of fresh powder to refill the powder supply. The powder consumption per object may be utilized to guide batching rules and/or powder refresh recommendations for subsequent builds.

In some examples, the apparatus may determine the build volume with the minimum fresh powder per object, where the “minimum fresh powder” and/or the “smallest quantity of manufacturing power consumption” may mean the minimum fresh powder per object to maintain a target quality metric (e.g., a b* of 4). The minimum fresh powder per object may be determined based on the simulation results (e.g., powder degradation simulation). In some examples, the apparatus may determine a distribution of the average fresh powder per object calculated for each build volume. For instance, the average fresh powder per object for each build volume may be calculated for amounts of objects for a quantity of replicants to produce distributions for each amount of objects (and/or for each spacing, for instance). In some examples, the apparatus may produce a box and whisker chart(s) of the average fresh powder per object. In some examples, the distributions (e.g., box and whisker chart(s)) may be utilized as a lookup table for amounts of objects in a batch associated with manufacturing powder consumption per object. For instance, the distributions and/or lookup table may be utilized to determine a build volume (e.g., batch size of a build volume, build height of a build volume, etc.) with a smallest quantity of manufacturing powder consumption per object. In some examples, the apparatus may adjust a manufacturing parameter (e.g., batching rule, build height rule, etc.) based on the build volume.

In some examples, the method 100 may include determining whether a demand condition is satisfied. A demand condition is a criterion or criteria indicating a change to manufacturing load (e.g., manufacturing load for a 3D printer(s) and/or factory, etc.). For instance, manufacturing load may change as manufacturing requests increase or decrease and/or as manufacturing quality increases or decreases. The demand condition may be utilized to determine whether there is a significant change in the distribution of objects. In some examples, a change in manufacturing requests (e.g., objects submitted for manufacturing) and/or manufacturing quality may impact a quantity of objects to be manufactured (e.g., manufactured within a timeframe or period). In a case that a demand condition is satisfied, a manufacturing parameter(s) (e.g., batching rule(s), build height rule(s), etc.) may be reevaluated. For instance, the method 100 may be triggered in response to a determination that a demand condition is satisfied. In some examples, determining 102 objects corresponding to a manufacturing period of 3D printing is performed in response to determining that a demand condition is satisfied.

In some examples, determining whether a demand condition is satisfied may include determining a Kullback-Leibler (KL) divergence between a first period distribution and a second period distribution. The first period distribution is a manufacturing load distribution from a first period and the second period distribution is a manufacturing load distribution from a second period. For instance, the first period distribution may indicate a distribution of manufactured objects (and/or manufacturing requests) within a week that is two weeks prior to a current time. The second period distribution may indicate a distribution of manufactured objects (and/or manufacturing requests) within a week that is one week prior to the current time. The KL divergence may indicate a degree of divergence or difference between the first period distribution and the second period distribution. In some examples, determining whether a demand condition is satisfied may include comparing the KL divergence to a threshold. Examples of the threshold may be 3, 4, 5, 5.5, 6, 7, or another value, etc.

In some examples, determining whether the demand condition is satisfied may include determining whether a quality metric satisfies a quality check threshold. For instance, the quality metric may be powder color (e.g., b*) and/or manufactured object quality (e.g., a degree to which the manufactured object geometry matches a target object geometry or is different from a target object geometry). For instance, if average powder color (e.g., b*) satisfies the quality check threshold (e.g., b*≥6) with a threshold frequency (e.g., a quantity of instances in a period such as three weeks or another period), the demand condition may be satisfied. In some examples, an image(s) of the manufacturing powder may be obtained by the apparatus and analyzed to determine an average powder color, which may be compared to the quality check threshold.

In some examples, if average manufactured object quality satisfies the quality check threshold (e.g., geometry difference≥3%) with a threshold frequency (e.g., a quantity of instances in a period such as three weeks or another period), the demand condition may be satisfied. In some examples, a scan(s) of the manufactured objects may be obtained by the apparatus and analyzed (e.g., compared to target 3D object model geometry) to determine an average manufactured object quality, which may be compared to the quality check threshold.

In a case that a demand condition is satisfied, the method 100 may be triggered to reevaluate a manufacturing parameter(s). For instance, batching rules may change based on changes to the input geometry of the objects. For instance, if an average orthotic size changed to producing larger orthotics (e.g., from a size 10 to a size 13) or orthotics with higher arches, etc., the demand condition may be satisfied to reevaluate the manufacturing parameter(s). In another example, if manufacturing requests for children's orthotics are received, the batch size with a smallest manufacturing powder consumption may change from 26 orthotics per build volume to 32 orthotics per build volume due to the reduced size of the object geometry.

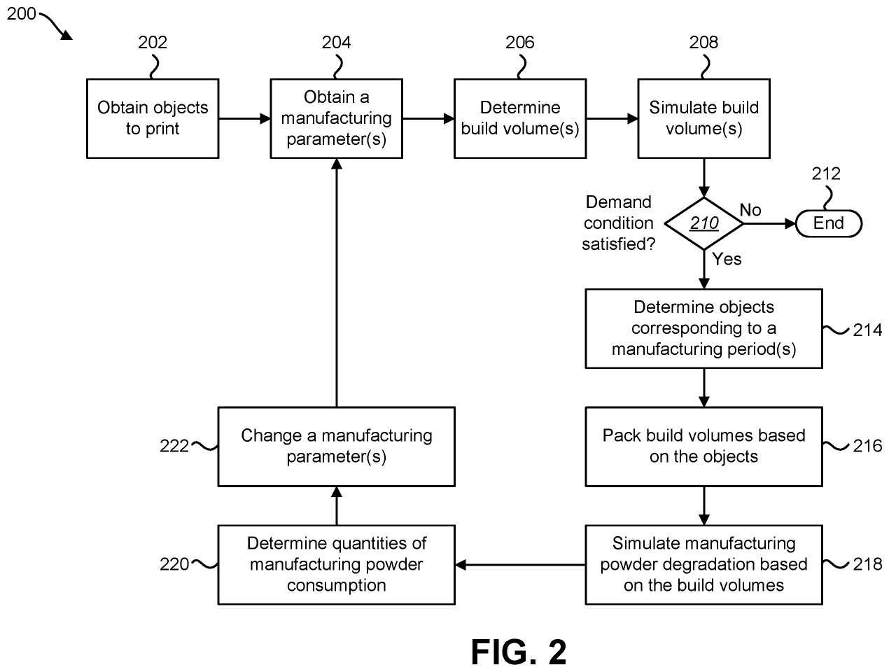

FIG. 2 is a flow diagram illustrating an example of a method 200 for manufacturing control based on powder degradation. For example, the method 200 may be performed to control an aspect or aspects of object manufacturing. The method 200 and/or an element or elements of the method 200 may be performed by an electronic device. For example, the method 200 may be performed by the apparatus 324 described in relation to FIG. 3.

The apparatus may obtain 202 objects to print. For example, the apparatus may receive 3D object models from another device (e.g., web server, remote computer via a network, etc.), may read 3D object models from a storage repository (e.g., memory, storage, etc.), may receive 3D object models from an input device, and/or may generate 3D object models.

The apparatus may obtain 204 manufacturing parameter(s). For example, the apparatus may determine manufacturing parameter(s), may receive a manufacturing parameter(s) from another device (e.g., web server, remote computer via a network, etc.), may read manufacturing parameter(s) from a storage repository (e.g., memory, storage, etc.), may receive manufacturing parameter(s) from an input device, and/or may generate manufacturing parameter(s). For instance, the apparatus may retrieve a default manufacturing parameter(s) from memory, may retrieve a manufacturing parameter(s) determined previously based on a simulated manufacturing powder degradation, and/or may receive a manufacturing parameter(s) from an input device (e.g., keyboard, mouse with a graphical user interface, touchscreen, etc.). Examples of a manufacturing parameter may include a batching rule, a build height rule, and/or a spacing rule, etc.

The apparatus may determine 206 a build volume(s). For instance, the apparatus may determine 206 the build volume(s) based on the 3D objects and the manufacturing parameter(s). In some examples, determining 206 the build volume(s) may include batching a build volume(s) (e.g., assigning an amount of objects to a build volume(s)) and/or packing a build volume(s) (e.g., determining a position and/or orientation for each object in a build volume). In some examples, the build volume(s) may be sent to a 3D printer(s) and/or a factory for manufacturing.

The apparatus may simulate 208 the build volume(s). For instance, the apparatus may simulate thermal behavior of the build volume(s), manufacturing powder degradation of the build volume(s), and/or manufactured object geometry of the build volume(s). In some examples, the apparatus may utilize a first principles approach (e.g., FEA) and/or a machine learning approach to simulate the build volume(s). For instance, the apparatus may utilize a machine learning model that is trained to infer voxel level thermal behavior, voxel stress, and/or powder degradation based on a build volume (e.g., 3D object model arrangement).

The apparatus may determine 210 whether a demand condition is satisfied. For instance, the apparatus may determine whether a significant change in manufacturing load has occurred. In some examples, determining 210 whether a demand condition is satisfied may be performed as described in relation to FIG. 1. In a case that the demand condition is not satisfied, operation may end 212.

In a case it is determined that the demand condition is satisfied, the apparatus may determine 214 objects corresponding to a manufacturing period(s). For instance, the apparatus may obtain and/or select 3D object models corresponding to a manufacturing period or periods. In some examples, determining 214 the objects may be performed as described in relation to FIG. 1.

The apparatus may pack 216 build volumes based on the objects. For example, the apparatus may determine positions and orientations for the objects in build volumes. In some examples, packing 216 the build volumes may be performed as described in relation to FIG. 1.

The apparatus may simulate 218 manufacturing powder degradation based on the build volumes. In some examples, simulating 218 manufacturing powder degradation may be performed as described in relation to FIG. 1 and/or FIG. 6.

The apparatus may determine 220 quantities of manufacturing powder consumption. For instance, the apparatus may calculate quantities of manufacturing powder consumption per object. In some examples, determining 220 quantities of manufacturing powder consumption may be performed as described in relation to FIG. 1.

The apparatus may change 222 a manufacturing parameter(s). For instance, the apparatus may change a batching rule, build height rule, and/or spacing rule. In some examples, the apparatus may select a batching rule, build height rule, and/or spacing rule based on a build volume with a smallest manufacturing powder consumption per object. For instance, the batching rule, build height rule, and/or spacing rule may be changed to adjust build volume determination and/or packing to result in performance similar to the build volume with the smallest manufacturing powder consumption per object. The changed manufacturing parameter(s) may be stored and/or updated in memory. The changed manufacturing parameter(s) may be obtained 204 for subsequent manufacturing.

FIG. 3 is a block diagram of an example of an apparatus 324 that may be used in controlling manufacturing based on powder degradation. The apparatus 324 may be a computing device, such as a personal computer, a server computer, a printer, a 3D printer, a smartphone, a tablet computer, etc. The apparatus 324 may include and/or may be coupled to a processor 328, a communication interface 330, and/or a memory 326. In some examples, the apparatus 324 may be in communication with (e.g., coupled to, have a communication link with) an additive manufacturing device (e.g., a 3D printer). In some examples, the apparatus 324 may be an example of 3D printer. The apparatus 324 may include additional components (not shown) and/or some of the components described herein may be removed and/or modified without departing from the scope of the disclosure.

The processor 328 may be any of a central processing unit (CPU), a semiconductor-based microprocessor, graphics processing unit (GPU), field-programmable gate array (FPGA), an application-specific integrated circuit (ASIC), and/or other hardware device suitable for retrieval and execution of instructions stored in the memory 326. The processor 328 may fetch, decode, and/or execute instructions stored on the memory 326. In some examples, the processor 328 may include an electronic circuit or circuits that include electronic components for performing a functionality or functionalities of the instructions. In some examples, the processor 328 may perform one, some, or all of the aspects, elements, techniques, etc., described in relation to one, some, or all of FIGS. 1-6.

The memory 326 is an electronic, magnetic, optical, and/or other physical storage device that contains or stores electronic information (e.g., instructions and/or data). The memory 326 may be, for example, Random Access Memory (RAM), Electrically Erasable Programmable Read-Only Memory (EEPROM), a storage device, an optical disc, and/or the like. In some examples, the memory 326 may be volatile and/or non-volatile memory, such as Dynamic Random Access Memory (DRAM), EEPROM, magnetoresistive random-access memory (MRAM), phase change RAM (PCRAM), memristor, flash memory, and/or the like. In some examples, the memory 326 may be a non-transitory tangible machine-readable storage medium (e.g., non-transitory tangible computer-readable medium), where the term “non-transitory” does not encompass transitory propagating signals. In some examples, the memory 326 may include multiple devices (e.g., a RAM card and a solid-state drive (SSD)).

The apparatus 324 may further include a communication interface 330 through which the processor 328 may communicate with an external device or devices (not shown), for instance, to receive and store the information pertaining to an object or objects. The communication interface 330 may include hardware and/or machine-readable instructions to enable the processor 328 to communicate with the external device or devices. The communication interface 330 may enable a wired or wireless connection to the external device or devices. In some examples, the communication interface 330 may include a network interface card and/or may also include hardware and/or machine-readable instructions to enable the processor 328 to communicate with various input and/or output devices, such as a keyboard, a mouse, a display, another apparatus, electronic device, computing device, printer, etc. In some examples, a user may input instructions and/or data into the apparatus 324 via an input device.

In some examples, the memory 326 may store model data 340. The model data 340 may include and/or indicate a model or models (e.g., 3D object model(s), 3D manufacturing build(s), etc.). For instance, the model data 340 may include and/or indicate 3D object models. The apparatus 324 may generate the model data 340 and/or may receive the model data 340 from another device.

In some examples, the memory 326 may store simulation instructions 341. The processor 328 may execute the simulation instructions 341 to simulate manufacturing powder degradation quality metrics for a set of build volumes. In some examples, determining the manufacturing powder degradation powder quality metrics may be performed as described in relation to FIG. 1, FIG. 2, and/or FIG. 6. For instance, the apparatus 324 may determine a powder quality metric (e.g., b*) for each build volume (e.g., each build volume packed with 3D object models). In some examples, the processor 328 may utilize a machine learning model(s) to predict and/or infer the powder quality metric as a b* component of a color space.

In some examples, the memory 326 may store consumption instructions 342. The processor 328 may execute the consumption instructions 342 to determine quantities of manufacturing powder consumption for the set of build volumes based on the manufacturing powder degradation metrics. For instance, the processor 328 may calculate an average powder consumption per object to maintain a target powder quality metric (e.g., b*=4) for each of the build volumes. In some examples, determining the quantities of manufacturing powder consumption may be performed as described in relation to FIG. 1 and/or FIG. 2. For instance, the processor 328 may determine a distribution of average powder (e.g., fresh powder) consumption per object for build volumes with a batch size. A distribution may be determined for each batch size (e.g., quantity of objects in a build volume) and/or for each object spacing. In some examples, the processor 328 may generate a data structure (e.g., lookup table) and/or chart (e.g., box and whisker chart) of the quantities of manufacturing powder consumption (e.g., distributions).

In some examples, the memory 326 may store selection instructions 344. In some examples, the processor 328 may execute the selection instructions 344 to select a build volume with a smallest quantity of manufacturing powder consumption (e.g., a smallest average quantity of manufacturing powder consumption per object to maintain a target powder quality metric). In some examples, the processor 328 may utilize the data structure (e.g., lookup table) and/or chart (e.g., box and whisker chart) of distributions to select a build volume (e.g., distribution of build volumes) with a smallest quantity of manufacturing powder consumption. In some examples, the processor 328 may select the build volume(s) as described in relation to FIG. 1 and/or FIG. 2. In some examples, selecting a build volume with a smallest quantity of manufacturing powder consumption may determine a batch size with a smallest quantity of manufacturing powder consumption.

In some examples, the memory 326 may store control instructions 345. In some examples, the processor 328 may execute the control instructions 345 to change a manufacturing procedure based on the selected build volume. For instance, the processor 328 may change a manufacturing parameter (e.g., batching rule and/or build height rule) based on the selected build volume. For instance, the processor 328 may change the manufacturing procedure by changing a batching rule based on the selected build volume (e.g., changing the batching rule to the batch size of the selected build volume). In some examples, the processor 328 may change the manufacturing procedure by changing a build height rule based on the selected build volume (e.g., changing a build height rule to the build height of the selected build volume). In some examples, the processor 328 may change the manufacturing procedure as described in relation to FIG. 1 and/or FIG. 2.

In some examples, the memory 326 may store operation instructions 346. In some examples, the processor 328 may execute the operation instructions 346 to perform an operation. For instance, the processor 328 may execute the operation instructions 346 to instruct a printer to print the 3D manufacturing build with the changed manufacturing procedure. For instance, the apparatus 324 may utilize the communication interface 330 to send the build to a printer(s) for printing.

In some examples, the operation instructions 346 may include 3D printing instructions. For instance, the processor 328 may execute the 3D printing instructions to print a 3D object or objects with the changed manufacturing procedure. In some examples, the 3D printing instructions may include instructions for controlling a device or devices (e.g., rollers, print heads, thermal projectors, and/or fuse lamps, etc.). For example, the 3D printing instructions may use a build to control a print head or heads to print an agent or agents in a location or locations specified by the build. In some examples, the processor 328 may execute the 3D printing instructions to print a layer or layers. In some examples, the processor 328 may execute the operation instructions 346 to present a visualization or visualizations (e.g., box and whisker charts) of the quantities of powder consumption, refresh ratios, and/or build heights on a display and/or send the visualization or visualizations to another device (e.g., computing device, monitor, etc.).

In some examples, an operation or operations described in relation to FIG. 3 may be performed in response to determining that a demand condition is satisfied. For instance, the processor 328 may execute demand condition instructions (not shown in FIG. 3) in the memory 326 to determine whether a demand condition is satisfied. In response to determining that the demand condition is satisfied, for instance, the processor 328 may execute the simulation instructions 341, consumption instructions 342, selection instructions 344, control instructions 345, and/or operation instructions 346.

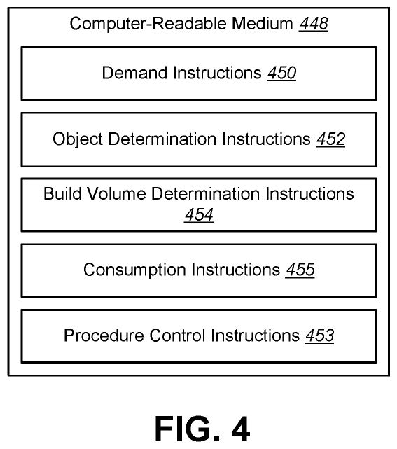

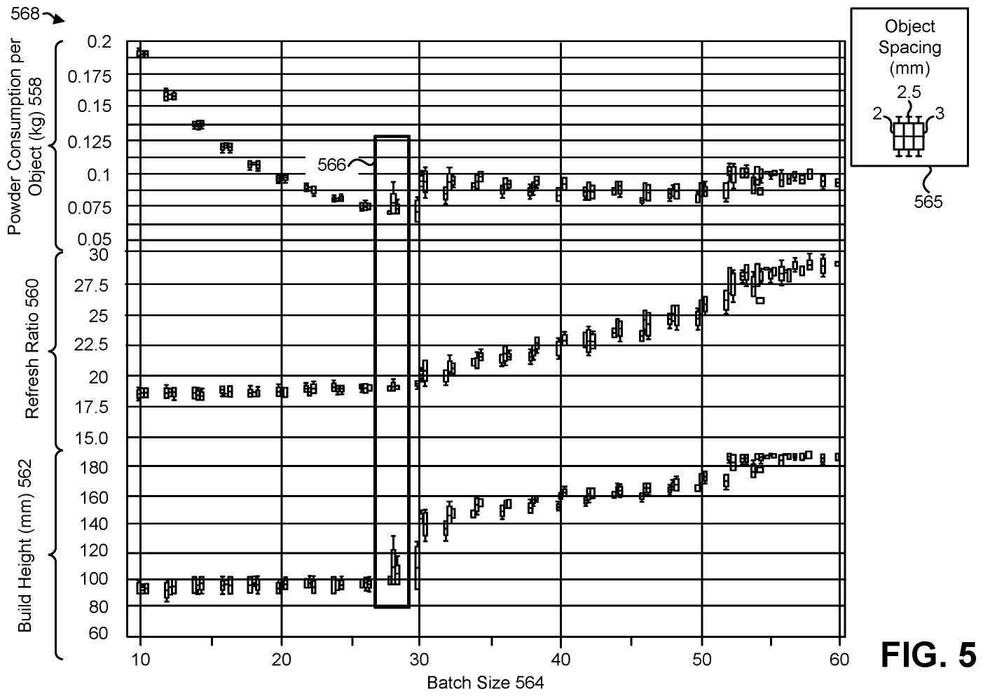

FIG. 4 is a block diagram illustrating an example of a computer-readable medium 448 for controlling manufacturing based on powder degradation. The computer-readable medium 448 is a non-transitory, tangible computer-readable medium. The computer-readable medium 448 may be, for example, RAM, EEPROM, a storage device, an optical disc, and the like. In some examples, the computer-readable medium 448 may be volatile and/or non-volatile memory, such as DRAM, EEPROM, MRAM, PCRAM, memristor, flash memory, and/or the like. In some examples, the memory 326 described in relation to FIG. 3 may be an example of the computer-readable medium 448 described in relation to FIG. 4. In some examples, the computer-readable medium 448 may include code, instructions, and/or data to cause a processor to perform one, some, or all of the operations, aspects, elements, etc., described in relation to one, some, or all of FIG. 1, FIG. 2, FIG. 3, FIG. 4, FIG. 5, and/or FIG. 6.

The computer-readable medium 448 may include data (e.g., information and/or executable instructions). For example, the computer-readable medium 448 may include demand instructions 450, object determination instructions 452, build volume determination instructions 454, consumption instructions 455, and/or procedure control instructions 453.

The demand instructions 450 may be instructions when executed cause a processor of an electronic device to determine that a demand condition is satisfied to produce a demand determination. For instance, the demand determination may indicate that the demand condition is satisfied. In some examples, determining whether a demand condition is satisfied may be performed as described in relation to FIG. 1, FIG. 2, and/or FIG. 3. In some examples, the processor may execute the demand instructions 450 to determine that the demand condition is satisfied by comparing a KL divergence (e.g., a KL divergence between manufacturing load distributions from different manufacturing periods) to a threshold.

The object determination instructions 452 may be instructions when executed cause the processor of the electronic device to determine, in response to the demand determination, objects corresponding to a manufacturing period. In some examples, determining the objects corresponding to a manufacturing period(s) may be performed as described in relation to FIG. 1.

The build volume determination instructions 454 may include instructions when executed cause the processor of the electronic device to determine build volumes that include the objects. In some examples, determining the build volumes may be performed as described in relation to FIG. 1, FIG. 2, and/or FIG. 3. For instance, the processor may pack 3D object models into build volumes for a range of batch sizes, object spacings, and/or replicants.

The consumption instructions 455 may include instructions when executed cause the processor of the electronic device to determine a quantity of manufacturing powder consumption for each of the build volumes. In some examples, determining the quantities of manufacturing powder consumption may be performed as described in relation to FIG. 1, FIG. 2, and/or FIG. 3.

The procedure control instructions 453 may include instructions when executed cause the processor of the electronic device to adjust a batching rule based on the quantity of manufacturing powder consumption of each of the build volumes. In some examples, adjusting the batching rule may be performed as described in relation to FIG. 1, FIG. 2, and/or FIG. 3. For instance, the processor may determine a build volume with a smallest manufacturing powder consumption and may adjust the batching rule by changing the batching rule to a batch size of the build volume.

FIG. 5 is a diagram illustrating examples of box and whisker charts 568 in accordance with some examples of the techniques described herein. For instance, FIG. 5 illustrates a first box and whisker chart of build height 562 over batch size 564, a second box and whisker chart of refresh ratio 560 over batch size 564, and a third box and whisker chart of fresh powder consumption per object 558 over batch size 564. In the example of FIG. 5, each box and whisker illustrates a distribution of values corresponding to a batch size 564 (e.g., quantity of objects in a build volume). For instance, each box and whisker may indicate a maximum value in a distribution, a minimum value in a distribution, an upper quartile in a distribution, a lower quartile in a distribution, and an average (e.g., mean or median) in a distribution. Each of the build volumes may be packed individually and may vary in arrangement. For instance, each build volume may include a build height 562 (in mm), which may denote a height in the build volume under which the objects are packed. FIG. 5 illustrates distributions for three object spacings 565 (e.g., 2 mm, 2.5 mm, and 3 mm) for some batch sizes.

In accordance with some examples of the techniques described herein, an apparatus may simulate manufacturing powder degradation for a set of build volumes. The apparatus may utilize the simulation results to determine refresh ratios (e.g., refresh ratios 560) and/or powder consumption per object (e.g., powder consumption per object 558). The powder consumption per object 558 has units of kilograms (kg) in FIG. 5. For instance, for each batch size, the apparatus may pack and simulate multiple build volume replicants. The apparatus may utilize the packing and simulation results to determine the distributions of the refresh ratio 560 and/or powder consumption per object 558.

In some examples of the techniques described herein, an apparatus may select a build volume(s) with a smallest powder consumption. Selecting the build volume(s) with a smallest powder consumption may indicate a batch size and/or build height associated with the build volume(s). In the example of FIG. 5, a build volume with a batch size 564 of 28 is selected 566. For instance, the selected 566 build volume has an overall smallest quantity of powder consumption per object 558 (over all object spacings, for example). In some examples, the batch size 564 (e.g., 28) may be utilized to change a batching rule for manufacturing.

For example, the selected 566 build volume may include 28 orthotics per build with a global minimum of powder consumption per object. The global minimum for powder consumption per object may combine a relatively high packing density in a quarter bucket build (where a quarter of the build volume includes the objects, for instance), meaning that objects may be manufactured at a high packing density while using a reduced refresh ratio (e.g., under 20%). This box and whisker charts 568 also illustrate other values in the design space. In this example, 28 objects per build may fill approximately a quarter of a build volume (compared to 90 objects per build which may fill a whole build volume, for instance). In some examples, selecting a build volume with reduced powder consumption may reduce manufacturing costs.

In some examples, a refresh ratio of powder utilized may depend on a combination of build volume packings. For instance, an example approach may utilize a 25% powder refresh ratio, a 2 mm part spacing, a 110 mm build height, and 28-object batch size. The 25% recycling ratio may allow a factory to print a combination of quarter bucket and half bucket builds, which may increase manufacturing throughput while balancing powder consumption. In this example, the quarter bucket builds may have a net impact of refreshing the system powder supply with high quality powder, while the half bucket builds may have a net impact of degrading the system powder supply. Printing a mixture of these two builds where ⅓ or more of all printed jobs are quarter buckets may result in stable powder quality.

FIG. 6 is a block diagram illustrating an example of engines 672 to simulate how much powder degradation will occur for a build volume (e.g., 3D print). As used herein, the term “engine” refers to circuitry (e.g., analog or digital circuitry, a processor, such as an integrated circuit, or other circuitry, etc.) or a combination of instructions (e.g., programming such as machine- or processor-executable instructions, commands, or code such as a device driver, programming, object code, etc.) and circuitry. Some examples of circuitry may include circuitry without instructions such as an application specific integrated circuit (ASIC), a Field Programmable Gate Array (FPGA), etc. A combination of circuitry and instructions may include instructions hosted at circuitry (e.g., an instruction module that is stored at a processor-readable memory such as random-access memory (RAM), a hard-disk, or solid-state drive, resistive memory, or optical media such as a digital versatile disc (DVD), and/or executed or interpreted by a processor), or circuitry and instructions hosted at circuitry.

The engines 672 may include a slicing engine 674. The slicing engine 674 may slice a build file to determine a plurality of voxels. The build file may include data that describes a plurality of objects to be printed within a build volume, including the pose of the objects within the build volume. The slicing engine 674 may slice the build file by dividing the build volume into a plurality of voxels. In some examples, the build volume may be a rectangular prism, and the voxels may be rectangular prisms. For example, the slicing engine 674 may slice the build volume with planes parallel to the XY plane, the YZ plane, and XZ plane to form the voxels. The 3D printer may have a printing resolution, such as a resolution in the XY plane and a resolution along the Z axis. The slicing engine 674 may slice the build file into voxels with sizes equal to the resolution of the 3D printer, into larger voxels, or into smaller voxels. There is a tradeoff between larger voxel sizes that allow for more efficient computation and smaller voxel sizes that provide a finer resolution of the powder degradation.

The engines 672 may include an agent delivery engine 676. The agent delivery engine 676 may determine the amount of agent that will be delivered to the powder at each voxel. The agent delivery engine 676 may determine the amount of fusing agent, the amount of detailing agent, the amount of binding agent, the amount of a property modification agent, the amount of a coloring agent, or the like that will be delivered. For example, the agent delivery engine 676 may determine the amount of agent that will be delivered based on the build file. The agent delivery engine 676 may compute a continuous tone map that indicates how much agent will be delivered to each voxel. The agent delivery engine 676 may use a deterministic approach to determine the amount of agent to be delivered to achieve or prevent coalescing (or another property) at various locations, may use a machine learning (e.g., deep learning) model to determine the amount of agent to be delivered, or the like. The machine learning model may be trained based on the deterministic approach to achieve similar results more quickly. For example, the machine learning model may quickly determine the amount of agent that will be received by a voxel with a lower resolution than the resolution than the printer without computing continuous tone (e.g., contone) maps at the print resolution. The agent delivery engine 676 may include a separate model or sub-engine to determine the amount of each agent used during the print process. The amount of agent delivered may depend on the model of the 3D printer, the version of instructions running on the 3D printer, the arrangement of the 3D printer, the settings of the 3D printer, the setup of the 3D printer, or the like. Accordingly, the agent delivery engine 676 may determine the amount of agent to be delivered based on the model of the 3D printer, the version of instructions, or the like.

The engines 672 may include an agent response engine 678. The agent response engine 678 may determine a temperature response that will be experienced by the powder at each voxel from the amount of the agent that will be delivered. For example, the 3D printer may apply energy to the build volume, and the amount of agent delivered to a voxel affects how much energy is absorbed by the powder at that voxel. Accordingly, the agent response engine 678 may determine the temperature response based on the amount of agent and the amount of energy to be delivered to the voxel. The agent response engine 678 may determine the amount of energy to be delivered or select a relationship between agent and temperature based on the model of the 3D printer, the version of instructions running on the 3D printer, the arrangement, the settings, the setup, or the like. In some examples, the 3D printer may deliver energy to select voxels without use of an agent. In such examples, the engines 672 may include an engine to determine the amount of energy delivered to each voxel without determining the amount of agent delivered. In some examples, the agent delivery engine 676 and/or the agent response engine 678 may perform deep learning operations to predict the thermal conditions in a fusing layer for the simulation engine 684.

The engines 672 may include a material state engine 682 to determine a coalescence state that will result for the powder at each voxel. For example, the material state engine 682 may determine which voxels include an object and which do not, based on the slices of the build file. The material state engine 682 may select a coalesced state for voxels that include an object and an uncoalesced state for voxels without an object. In some examples, the material state engine 682 may include various states between coalesced and uncoalesced for voxels that include an object and loose powder.

The engines 672 may include a simulation engine 684 to determine a plurality of thermal states that will be experienced by the powder at each voxel as a result of printing the build specified by the build file. For example, the simulation engine 684 may determine an initial thermal state of each voxel based on the results from the agent delivery engine 676 and the agent response engine 678. The simulation engine 684 may determine thermal states after the initial thermal state based on conduction of heat among voxels and loss of heat to the environment. The simulation engine 684 may determine the amount of conduction based on the coalescence state of each voxel determined by the material state engine 682.

The simulation engine 684 may progress through a series of time increments and determine the thermal state of each voxel at each time increment. In some examples, not yet printed voxels may be ignored until they are formed. In examples, the simulation engine 684 may generate a four-dimensional (4D) representation of the build volume that includes a temperature for each time and voxel location (e.g., 3D cartesian location). At each time increment, the simulation engine 684 may compute the thermal states for each voxel based on the thermal states from the immediately previous increment, the agent response for any new voxels, and the loss of thermal energy at the boundary of the build volume. The time increment may be selected based on the desired resolution. Larger increments may allow for quicker computation and smaller increments may provide more precise results for the thermal experience of each voxel. Different time increments may be selected for time when the printer is printing versus when the build volume is cooling. In some examples, the time increments for printing may be selected to have a plurality of time increments during the formation of each voxel (e.g., at the resolution generated by the slicing engine 674). The time increments during cooling may be larger (e.g., an order of magnitude or two larger). The simulation engine 684 may generate thermal states for each voxel from its formation until the end of the cooling period.

The engines 672 may include a stress engine 660. The stress engine 660 may calculate a stress to the powder at each voxel. The stress engine 660 may determine the stress based on the plurality of thermal states. The stress engine 660 may determine impacts of environmental factors on the amount of degradation of the powder at each voxel. As used herein, the term “environment” refers to anything at the voxel or surrounding the voxel that affects the degradation of the powder at a voxel. The term “environmental factor” refers to an attribute or set of attributes of the environment that affect the degradation of the powder at a voxel. The environmental factors may include heat, oxygen, agents, or the like. The term “impact” refers to a value (e.g., an alphanumeric value) representative of the influence of the environmental factor on the degradation of the powder. The impact may represent how the environmental factor will interact with the stress to produce degradation of the powder (e.g., how the environmental factor will amplify or dampen the effects of the stress). In the illustrated example, the stress engine 660 includes an initial state engine 662, a thermal engine 664, an oxidation engine 666, and an agent engine 668. The initial state engine 662 may determine an initial value indicative of an initial amount of powder degradation prior to printing. For example, the initial state engine 662 may determine the initial value based on the quality metric (e.g., b*) of the powder before printing, which may be determined from measuring the powder or based on the results of a previous simulation. Measurements may be input by a user, received from a measuring device, or retrieved from a non-transitory computer-readable medium. For some materials, the change in quality metric may be non-linearly related to the stress. For example, the change in quality metric for a particular stress may depend on the initial state of the quality metric. The initial state engine 662 may determine the initial value by converting the initial quality metric to a value in a domain with a linear relationship to a stress.

The thermal engine 664 may determine heat interactions with the powder at the voxel that will result in stress to the powder. For example, the thermal engine 664 may determine the stress to each voxel from the thermal states of that voxel throughout the printing process. The thermal engine 664 may determine the thermal stress based on a version of the Arrhenius equation. In an example, the thermal engine 664 may compute the thermal stress according to Equation (10):

$${σ}_{Thermal} = {\sum }_{m} {t}_{m} {e}^{( {a}_{0} - \frac{{E}_{a}}{{RT}_{m}} )} \qquad ( 10 )$$

Where σ_{Thermal} is the thermal stress at a voxel, the sum is over all time increments m, tₘ is the duration of a time increment m, a₀ is a constant specific to the material, Eₐ is the activation energy and is specific to the material and environment, R is the gas constant, and Tₘ is the temperature of the voxel at time increment m. In some examples, some time increments may have different lengths.

The oxidation engine 666 may determine oxidative interaction with the powder at the voxel that will result in stress to the powder. For example, the amount of degradation may depend on the amount of oxygen present at each voxel, which may in turn depend on whether oxygen is able to diffuse away from the voxel. The oxidation engine 666 may determine based on the pose of objects in the build volume whether there is coalesced powder blocking oxygen from diffusing. For example, the oxidation engine 666 may use the results from the material state engine 682 to determine which voxels will be in a coalesced state that prevents diffusion. Based on the states of the voxels, the oxidation engine 666 may determine how much oxygen is able to diffuse away from the voxel. The oxidation engine 666 may determine a value for each voxel indicative of how much interaction there will be between oxygen and the powder at that voxel, which value may be referred to as an oxidation metric.

The agent engine 668 may determine printing agent interaction with the powder at the voxel that will result in stress to the powder. For example, a detailing agent, a fusing agent, a binding agent, a property modification agent, a coloring agent, or the like may be applied to the powder. The amount of degradation of the powder may depend on the amount of agent present at each voxel or at neighboring voxels. The agent engine 668 may receive from the agent delivery engine 676 an indication of how much agent will be delivered to each voxel. The agent engine 668 may determine a value for each voxel indicative of how much the agents may interact with that voxel, which value may be referred to as an agent metric. The agent engine 668 may use the indication received from the agent delivery engine 676 as the agent metric or may compute the agent metric based on the indication.

The engines 672 may include a degradation engine 670. The degradation engine 670 may determine an amount of degradation of the powder at the voxel based on the stress. For example, the degradation engine 670 may compute the amount of degradation based on the initial value from the initial state engine 662, the thermal stress from the thermal engine 664, the oxidation metric from the oxidation engine 666, and the agent metric from the agent engine 668. In some examples, the degradation engine 670 may receive multiple values from the initial state engine 662, the thermal engine 664, the oxidation engine 666, and the agent engine 668. For example, the agent engine 668 may include a value for each type of agent that may interact with a voxel, or separate values may be produced based on separate equations or models that capture different ways in which heat, oxygen, or agent interact with the powder at the voxel.

The degradation engine 670 may compute, for each voxel, a quality metric or change in quality metric that will result from the particular print job. In an example using PA 12, the degradation engine 670 may compute a b* value that will result from the print job or a change in b* value that will result from the print job. In some examples, the degradation engine 670 may compute a value indicative of the amount of degradation in the same domain as the initial value from the initial state engine 662 and convert the computed value into the quality metric domain (e.g., the b* domain). In examples, the degradation engine 670 may compute the quality metric directly without first computing a value in an intermediate domain.

The degradation engine 670 may include a machine learning model to compute the quality metric based on the values from the stress engine 660. The machine learning model may include a support vector regression, a neural network, or the like. For each voxel, the machine learning model may receive the initial value from the initial state engine 662, the thermal stress, the oxidation metric, the agent metric, or multiple such values and output the quality metric or change in quality metric for that voxel that will result from the print job. The machine learning model may be trained based on data from actual print jobs. For example, the inputs for the machine learning model during training may be computed based on the build file for the actual print job. The ground truth for the output from the machine learning model may be determined by measuring the quality metric (e.g., the b* value) for the powder at a particular voxel (e.g., a sample of powder from the particular voxel). The machine learning model can be trained using values in the quality metric domain as ground truth, or the ground truth quality metric values can be converted to ground truth intermediate values used to train the machine learning model. In some examples, the quality metric(s) produced by the degradation engine 670 may be an example of the quality metric(s) described herein. For instance, the quality metric(s) may be provided to the setup engine 680. In some examples, an engine or engines of the engines 672 may be utilized to determine manufacturing powder degradation and/or manufacturing powder consumption as described herein. For instance, the agent delivery engine 676, the agent response engine 678, the material state engine 682, the simulation engine 684, the stress engine 660 and/or the degradation engine 670 may be included in the apparatus 324 described in relation to FIG. 3 in some examples.

The engines 672 may include a setup engine 680. The setup engine 680 may select a setup of the three-dimensional print based on the amount of degradation. For example, the setup engine 680 may select a manufacturing parameter(s) to use during the three-dimensional print. The setup engine 680 may include determined rules (e.g., batching rule(s), build height rule(s), spacing rule(s), etc.), previously specified rules, and/or user specified rules for manufacturing. The setup engine 680 may determine, based on a quality metric for the recycled powder, how much fresh powder to add to meet and/or maintain a target powder quality level. The quality metric for the recycled powder may have been measured or computed by the degradation engine 670 for a previous print job. In a PA 12 example, the setup engine 680 may compute the b* value that results from combining recycled and fresh powder by computing a weighted root mean square of the b* values for each powder added, weighted by the amount of that powder added. In some examples, the setup engine 680 may select the setup of the three-dimensional print by modifying manufacturing parameter(s) for the three-dimensional printer(s), modifying the build volume, or the like.

The engines 672 may include a print engine 690. The print engine 690 may instruct a 3D printer to print the print job with the selected setup. For example, the print engine 690 may transmit a build file, indications of printer settings, indications of the amount of fresh or recycled powder to use, or the like to the 3D printer and may indicate to the 3D printer to print using the transmitted information. The 3D printer may operate according to the transmitted information to form a build volume corresponding to the build file according to the specified settings with powder from the specified sources.

Some examples of the techniques described herein may help to determine how much fresh powder to be added for a build. For instance, it may be difficult to identify and/or selectively avoid reclaiming specific powder regions that include highly degraded powder when processing a build trolley.

In a factory setting, hundreds of objects may be produced in a day. Each object may be customized. When each job is different, it may be helpful to handle demand variability at the production floor. For instance, each time there is a significant change in demand (e.g., manufacturing requests and/or powder quality), the manufacturing parameter(s) may be updated. Some examples of the techniques described herein may be utilized in a factory environment where the powder consumption-based workflow may reflect updated manufacturing parameter(s) (e.g., powder refresh ratio, build height rule, batching rule, etc.) when a change is detected. For instance, when a change is detected, new manufacturing parameters may be generated by simulating the manufacturing behavior of characteristic parts and/or enumerating options (e.g., batching rule options, build height rule options, spacing options, etc.) as described herein.

Some examples of the techniques described herein may provide simulation of build volumes from a characteristic set of objects. Some examples of the techniques described herein may provide simulation of powder degradation over varying packing densities, object spacings, build heights, and/or batch sizes. Some examples of the techniques described herein may determine manufacturing parameters (e.g., batching rule, build height rule, and/or spacing rule) for reducing powder consumption while preserving a level of powder quality. Some examples of the techniques described herein may provide visualization of a design space.

As used herein, the term “and/or” may mean an item or items. For example, the phrase “A, B, and/or C” may mean any of: A (without B and C), B (without A and C), C (without A and B), A and B (without C), B and C (without A), A and C (without B), or all of A, B, and C.

While various examples are described herein, the disclosure is not limited to the examples. Variations of the examples described herein may be implemented within the scope of the disclosure. For example, aspects or elements of the examples described herein may be omitted or combined.

1. A method, comprising:
determining objects corresponding to a manufacturing period of three dimensional (3D) printing;
packing build volumes based on the objects;
simulating manufacturing powder degradation based on the build volumes;
determining a quantity of manufacturing powder consumption based on the manufacturing powder degradation; and
adjusting a manufacturing parameter based on the quantity of manufacturing powder consumption.

2. The method of claim 1, wherein determining the objects comprises selecting the objects based on object category.

3. The method of claim 1, further comprising determining a quantity of build volumes.

4. The method of claim 3, wherein determining the quantity of build volumes is based on a quantity of object packing amounts, quantity of object spacings, and a quantity of replicants.

5. The method of claim 1, further comprising:
determining the quantity of manufacturing powder consumption per object for each of the build volumes;
selecting a build volume with a smallest quantity of manufacturing powder consumption per object; and wherein
adjusting the manufacturing parameter comprises changing a batching rule based on the selected build volume.

6. The method of claim 1, further comprising determining whether a demand condition is satisfied.

7. The method of claim 6, wherein determining the objects corresponding to the manufacturing period is performed in response to determining that the demand condition is satisfied.

8. The method of claim 6, wherein determining whether the demand condition is satisfied comprises:
determining a Kullback-Leibler (KL) divergence between a first period distribution and a second period distribution; and
comparing the KL divergence to a threshold.

9. The method of claim 6, wherein the determining whether the demand condition is satisfied comprises determining whether a quality metric satisfies a quality check threshold.

10. An apparatus, comprising:
a memory; and
a processor coupled to the memory, wherein the processor is to:
simulate manufacturing powder degradation quality metrics for a set of build volumes;
determine quantities of manufacturing powder consumption for the set of build volumes based on the manufacturing powder degradation quality metrics;
select a build volume with a smallest quantity of manufacturing powder consumption; and
change a manufacturing procedure based on the selected build volume.

11. The apparatus of claim 10, wherein the processor is to change the manufacturing procedure by changing a batching rule based on the selected build volume.

12. The apparatus of claim 11, wherein the processor is to change the manufacturing procedure by changing a build height rule based on the selected build volume.

13. A non-transitory tangible computer-readable medium comprising instructions when executed cause a processor of an electronic device to:
determine that a demand condition is satisfied to produce a demand determination;
determine, in response to the demand determination, objects corresponding to a manufacturing period;
determine build volumes that include the objects;
determine a quantity of manufacturing powder consumption for each of the build volumes; and
adjust a batching rule based on the quantity of manufacturing powder consumption of each of the build volumes.

14. The non-transitory tangible computer-readable medium of claim 13, wherein the instructions when executed cause the processor of the electronic device to:
determine a build volume with a smallest manufacturing powder consumption; and
adjust the batching rule by changing the batching rule to a batch size of the build volume.

15. The non-transitory tangible computer-readable medium of claim 13, wherein the instructions when executed cause the processor of the electronic device to determine that the demand condition is satisfied by comparing a Kullback-Leibler (KL) divergence to a threshold.
